(19) United States
(12) Patent Application Publication
(10) Pub. No.: US 2010/0258899 A1
(43) Pub. Date: Oct. 14, 2010

(54) SCHOTTKY DIODE DEVICE WITH AN EXTENDED GUARD RING AND FABRICATION METHOD THEREOF

(76) Inventors: Chih-Tsung Huang, Miaoli County (TW); Jhih-Siang Huang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/420,060

(22) Filed: Apr. 8, 2009

(51) Int. Cl. H01L 29/872; H01L 21/329

(52) U.S. Cl. 257/484; 438/581; 257/476; 257/E29.338; 257/E21.359

(57) ABSTRACT

A Schottky diode device includes a silicon substrate, an epitaxial silicon layer on the silicon substrate, an annular trench in a scribe line region that encompasses the epitaxial silicon layer, an insulation layer on interior sidewall of the annular trench, a silicide layer on the epitaxial silicon layer, a conductive layer on the silicide layer, and a guard ring in the epitaxial silicon layer, wherein the guard ring butts the insulation layer.

### BACKGROUND OF THE INVENTION

1. Field of the Invention

The present invention relates to a Schottky diode device with an extended guard ring and, more particularly, to a Schottky rectifier device with very low forward voltage drop and a method of making the same.

2. Description of the Prior Art

As known in the art, a Schottky diode uses a metal-semiconductor junction as a Schottky barrier. For example, gold, silver or platinum silicide barrier may be used as the schottky barrier to a silicon substrate instead of a semiconductor-semiconductor junction or PN junction as in conventional diodes. This Schottky barrier results in both very fast switching times and low forward voltage drop.

FIG. 1 is a schematic, cross-sectional diagram illustrating a conventional Schottky diode device 100. As shown in FIG. 1, the conventional Schottky diode device 100 is fabricated on an N type epitaxial silicon layer 210. The N type epitaxial silicon layer 210 may be grown from an N type heavily doped silicon substrate 200 by conventional epitaxial growing methods. An annular shaped oxide layer 110 such as silicon dioxide is formed on a surface of the N type epitaxial silicon layer 210 and defines an active area opening 300, in which a silicide layer 120 is formed on the N type epitaxial silicon layer 210 and a conductive layer 124 is formed on the silicide layer 120. The conductive layer 124 fills the active area opening 300 and borders the annular shaped oxide layer 110. On the backside of the N type heavily doped silicon substrate 200, a conductive layer 224 is provided and an ohmic contact is created between the N type heavily doped silicon substrate 200 and the conductive layer 224. A P type guard ring 230 is provided in the N type epitaxial silicon layer 210. The P type guard ring 230 is situated underneath the annular shaped oxide layer 110.

The annular shaped oxide layer 110 can prevent the solder paste from contacting the N type epitaxial silicon layer 210 during soldering process. The solder paste may cascade from the top surface of the conductive layer 124 and may contact the N type epitaxial silicon layer 210, causing short circuiting. The annular shaped oxide layer 110 can prevent this from occurring. In addition, the conventional Schottky diode device 100 is surrounded by a scribe line region 310 along the outer periphery of the annular shaped oxide layer 110. The last step of the fabrication process of the conventional Schottky diode device 100 is dicing the wafer along the scribe line region 310, thereby forming separate discrete devices. A silicide layer 122 and a P type doped region 232 are formed within the scribe line region 310. The P type guard ring 230 is spaced apart from the P type doped region 232.

However, the above-described prior art Schottky diode device 100 has several drawbacks. First, due to the restricted chip real estate, it is difficult to increase the active contact area of the Schottky diode device and thus the forward voltage drop is hard to decrease. Second, the P-N junction 230a between the P type guard ring 230 and the N type epitaxial silicon layer 210 is abrupt and may become a reverse leakage path. Third, the conductive layer 124 of the conventional Schottky diode device 100 directly contacts with and partially covers the annular shaped oxide layer 110. When the Schottky diode device 100 is operated at high temperatures, the difference between the coefficient of thermal expansion of metal and that of silicon dioxide can lead to interface rupture or de-lamination between the conductive layer 124 and the annular shaped oxide layer 110. This results in increased reverse current and may cause device failure.

### SUMMARY OF THE INVENTION

It is one object of the present invention to provide an improved Schottky diode device structure in order to overcome the shortcomings and to solve the above-mentioned prior art problems.

According to the claimed invention, a Schottky diode device structure with an extended guard ring includes a silicon substrate; an epitaxial silicon layer on the silicon substrate; an annular trench in a scribe line region encompassing the epitaxial silicon layer; an insulation layer at least on a sidewall of the annular trench; a silicide layer on the epitaxial silicon layer; a conductive layer on the silicide layer, the conductive layer being spaced apart from the insulation layer; and a guard ring in the epitaxial silicon layer and the guard ring butting the insulation layer.

In one aspect, there is provided a method for fabricating a Schottky diode device including providing a silicon substrate; growing an epitaxial silicon layer on the silicon substrate; forming a first dielectric layer on the epitaxial silicon layer; performing an ion implantation process to form a guard ring in the epitaxial silicon layer; removing the first dielectric layer; forming a second dielectric layer on the epitaxial silicon layer; etching the second dielectric layer, the guard ring, the epitaxial silicon layer and the silicon substrate to form an annular trench; forming an insulation layer on a sidewall of the annular trench; removing the second dielectric layer thereby exposing the epitaxial silicon layer; forming a silicide layer on the epitaxial silicon layer; and forming a conductive layer on the silicide layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic, cross-sectional diagram illustrating a conventional Schottky diode device.

FIG. 2 is a schematic, cross-sectional diagram illustrating a novel Schottky diode device structure in accordance with one preferred embodiment of this invention.

FIG. 3 to FIG. 9 are schematic, cross-sectional diagrams showing the process steps of fabricating the Schottky diode device structure of FIG. 1 according to one embodiment of this invention.

FIG. 10 to FIG. 16 are schematic, cross-sectional diagrams showing the process steps of fabricating a Schottky diode device structure according to another embodiment of this invention.

### DETAILED DESCRIPTION

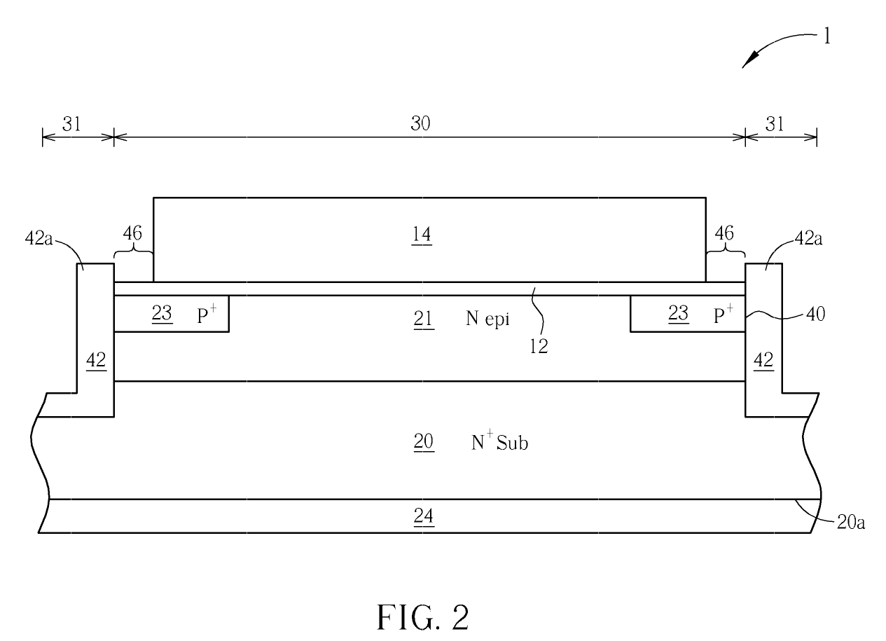

FIG. 2 is a schematic, cross-sectional diagram illustrating a novel Schottky diode device structure 1 with an extended guard ring in accordance with one preferred embodiment of this invention. As shown in FIG. 2, the Schottky diode device structure 1 is fabricated on an N type epitaxial silicon layer 21. The N type epitaxial silicon layer 21 may be grown from an N type heavily doped silicon substrate 20 by conventional epitaxial growing methods. A scribe line region 31 encompasses and surrounds the N type epitaxial silicon layer 21. An annular, recessed trench region 40 is formed within the scribe line region 31 by etched through the N type epitaxial silicon layer 21 and down to the N type heavily doped silicon substrate 20. According to the preferred embodiment of this invention, the annular, recessed trench region 40 has a width of about 30 micrometers and a depth that is greater than the thickness of the N type epitaxial silicon layer 21. In another embodiment, the annular, recessed trench region 40 has a depth that is deeper than the P-N junction. For example, the annular, recessed trench region 40 has a depth of about 10 micrometers. The annular, recessed trench region 40 has a substantially vertical sidewall that is composed of the N type epitaxial silicon layer 21 and a portion of the N type heavily doped silicon substrate 20. The bottom of the annular, recessed trench region 40 is the N type heavily doped silicon substrate 20. One germane feature of this invention is that the annular, recessed trench region 40 directly defines the active area 30 that is analogous to an isolated silicon island.

According to the preferred embodiment of this invention, an extended P⁺ guard ring 23 is provided in the N type epitaxial silicon layer 21. The extended P⁺ guard ring 23 is a continuous diffusion region that extends outward to the sidewall of the annular, recessed trench region 40 or scribe line region 31. According to the preferred embodiment of this invention, the extended P⁺ guard ring 23 may have a width of about 15-35 micrometers, preferably 20-30 micrometers. Likewise, on the backside of the N type heavily doped silicon substrate 20, a conductive layer 24 is provided and an ohmic contact is created between the N type heavily doped silicon substrate 20 and the conductive layer 24.

A silicide layer 12 such as NiSi, PtSi, TiSi or the like is formed on the planar surface of the N type epitaxial silicon layer 21 within the active area 30. A conductive layer 14 such as Ti, Ni, Ag or any combination thereof is disposed on the silicide layer 12. It is noteworthy that the silicide layer 12 covers the entire active area 30. According to the preferred embodiment of this invention, the conductive layer 14 does not covers the entire active area 30, instead, the conductive layer 14 is pull back and maintains an annular space 46, for example, 5-15 micrometers, between the conductive layer 14 and the annular, recessed trench region 40 that surrounds the N type epitaxial silicon layer 21.

According to the preferred embodiment of this invention, an insulation layer 42 is formed on the sidewall and the bottom of the annular, recessed trench region 40. The extended P⁺ guard ring 23 butts the insulation layer 42. According to the preferred embodiment of this invention, the insulation layer 42 has a thickness of about 0.1-2 micrometers, preferably 0.3-0.8 micrometers, more preferably 0.5 micrometers. According to the preferred embodiment of this invention, the insulation layer 42 is a thermal oxide layer and includes an upwardly protruding portion 42a. The upwardly protruding portion 42a has a height of about 0.5 micrometers above the surface of the silicide layer 12. The upwardly protruding portion 42a functions as a dam for blocking solder paste overflow during the subsequent soldering process. According to the preferred embodiment of this invention, the insulation layer 42 does not contact with the conductive layer 14 and because of the annular space 46 the metal-oxide interface rupture or de-lamination can be prevented when the Schottky diode device structure 1 is operated at high temperatures. Further, since the sidewall and bottom of the annular, recessed trench region 40 are both covered with the insulation layer 42, the overflow solder paste will not contact the N type epitaxial silicon layer 21 during the subsequent soldering process, thereby improving the process window and the reliability.

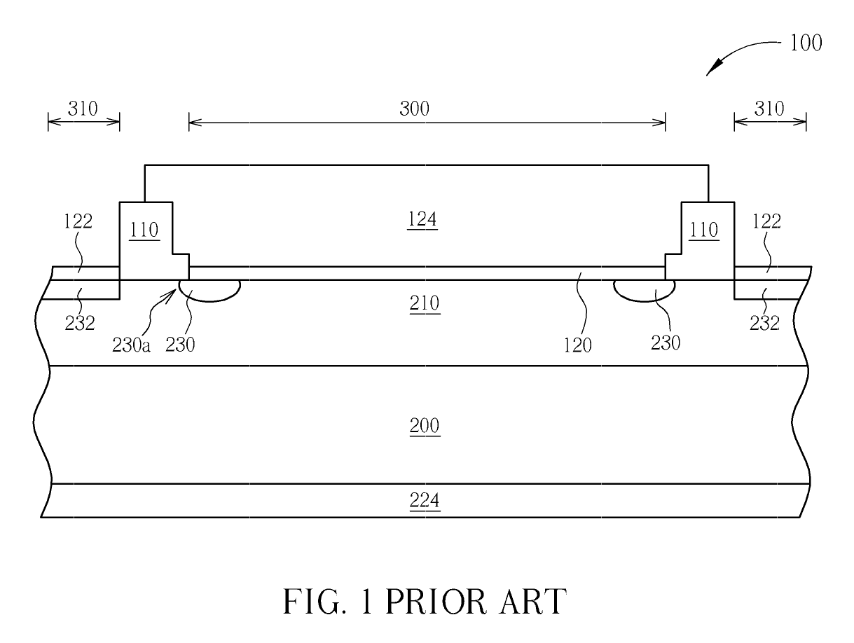

The present invention Schottky diode device structure 1 includes at least the following advantages and technical features. First, the active area 30 of the Schottky diode device structure 1 is directly defined by the annular, recessed trench region 40 within the scribe line region 31. By doing this, the surface area of the active area 30 gains about 32% increase when compared to the prior art Schottky diode device and can thus significantly decrease the forward voltage drop, improve forward surge ability. The increased surface area of the active area 30 also improves the heat dissipating efficiency of the device, thereby improving the device performance when the device is reverse biased at high temperatures. Second, the extended P⁺ guard ring 23 of the Schottky diode device structure 1 can completely solve the leakage problem resulting from the abrupt P-N junction 230a (FIG. 1) of the prior art Schottky diode device, thereby providing better electrostatic discharge (ESD) protection ability. Third, since the insulation layer 42 does not contact with the conductive layer 14 and because of the annular space 46, the metal-oxide interface rupture or de-lamination can be prevented when the Schottky diode device structure 1 is operated at high temperatures.

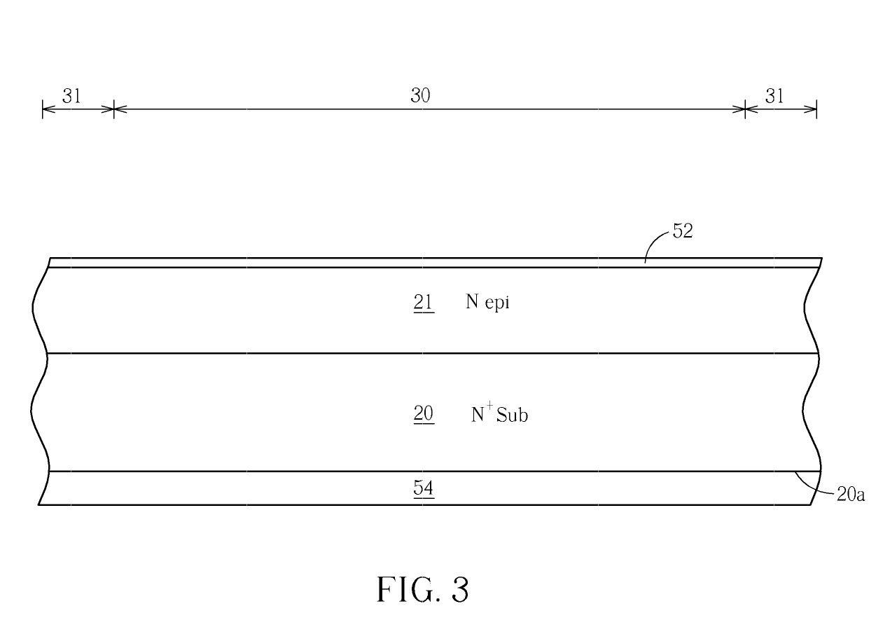

FIG. 3 to FIG. 9 are schematic, cross-sectional diagrams showing the process steps of fabricating the Schottky diode device structure 1 of FIG. 2 according to this invention, wherein like numeral numbers designate like elements, layers or regions. As shown in FIG. 3, an N type heavily doped silicon substrate 20 is provided. A thick silicon oxide layer 54 is formed on the backside 20a of the N type heavily doped silicon substrate 20. The thick silicon oxide layer 54 has a thickness of about 4000-6000 angstroms. An epitaxial silicon growth process is performed to grow an N type epitaxial silicon layer 21 on the N type heavily doped silicon substrate 20. Thereafter, an oxidation process is carried out to form a thin silicon oxide layer 52 on the N type epitaxial silicon layer 21. The thin silicon oxide layer 52 has a thickness of about 500 angstroms.

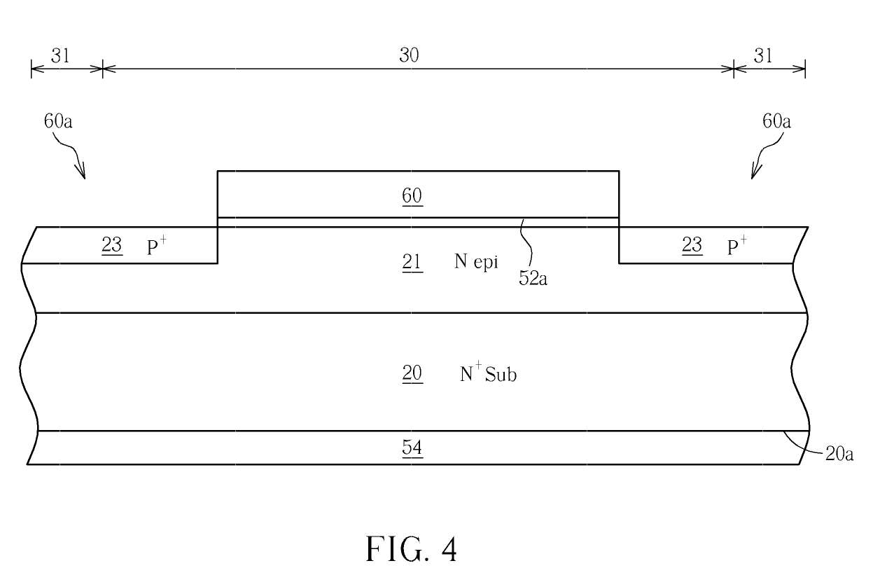

As shown in FIG. 4, a photoresist pattern 60 is formed on the silicon oxide layer 52. The photoresist pattern 60 has an opening 60a that defines the surface area of the N type epitaxial silicon layer 21 to be doped with P type dopants. It is noteworthy that the opening 60a overlaps with a periphery of the active area 30 and the entire scribe line region 31. Subsequently, an ion implantation process is carried out to implant P type dopants into the N type epitaxial silicon layer 21 through the opening 60a, thereby forming a P⁺ guard ring 23. After the ion implantation process, an etching process is performed to remove a portion of the thin silicon oxide layer 52 through the opening 60a, thereby forming silicon oxide layer 52a. The photoresist pattern 60 is then stripped off. According to another embodiment of this invention, after forming the P⁺ guard ring 23, the photoresist pattern 60 is first stripped, and the thin silicon oxide layer 52 is then completely removed.

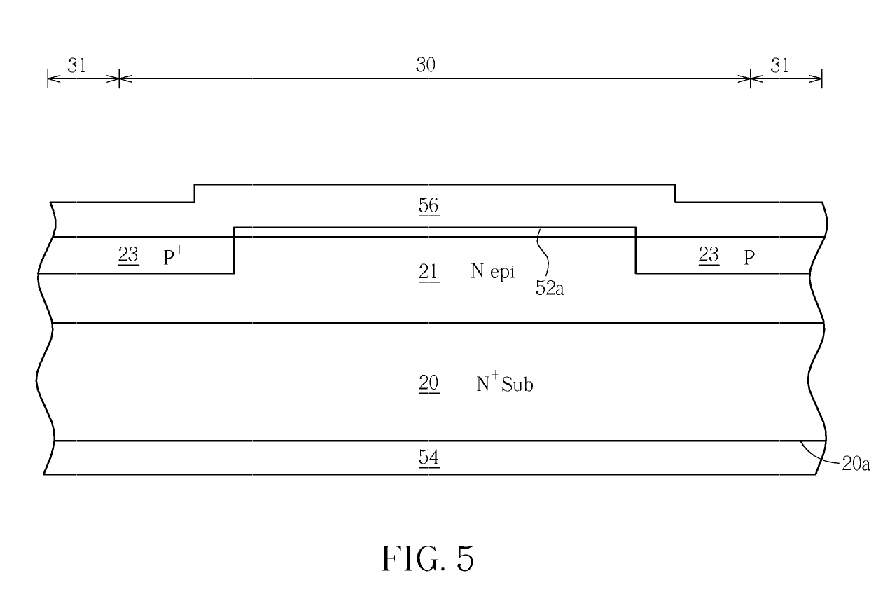

As shown in FIG. 5, after stripping the photoresist pattern 60, a thermal drive-in process is carried out to activate the dopants in the P⁺ guard ring 23. A chemical vapor deposition (CVD) process is performed to deposit a conformal silicon nitride layer 56 on the N type epitaxial silicon layer 21 and on the silicon oxide layer 52a. According to the preferred embodiment of this invention, the silicon nitride layer 56 has a thickness of about 800-1200 angstroms.

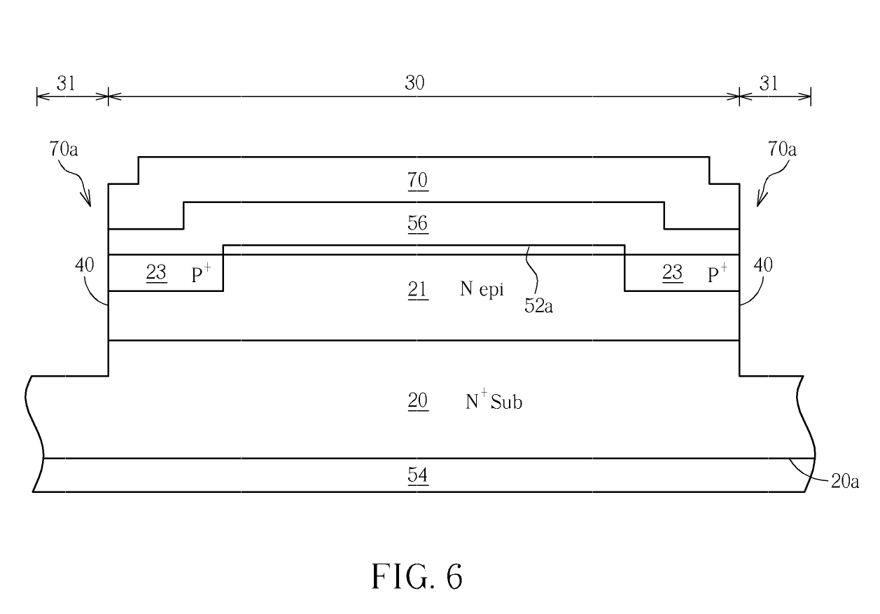

As shown in FIG. 6, a photoresist pattern 70 is formed on the silicon nitride layer 56. The photoresist pattern 70 has an opening 70a that defines the scribe line region 31. Subsequently, using the photoresist pattern 70 as an etch hard mask, a plasma dry etching process is carried out to anisotropically etch through the silicon nitride layer 56, the P+ guard ring 23, the N type epitaxial silicon layer 21, down deep to the N type heavily doped silicon substrate 20. At this point, an island like active area 30 and an annular, recessed trench region 40 are formed concurrently. The annular, recessed trench region 40 has a width of about 30 micrometers and a depth that is greater than the thickness of the N type epitaxial silicon layer 21. According to the preferred embodiment of this invention, the annular, recessed trench region 40 has a depth of about 10 micrometers. The photoresist pattern 70 is then removed.

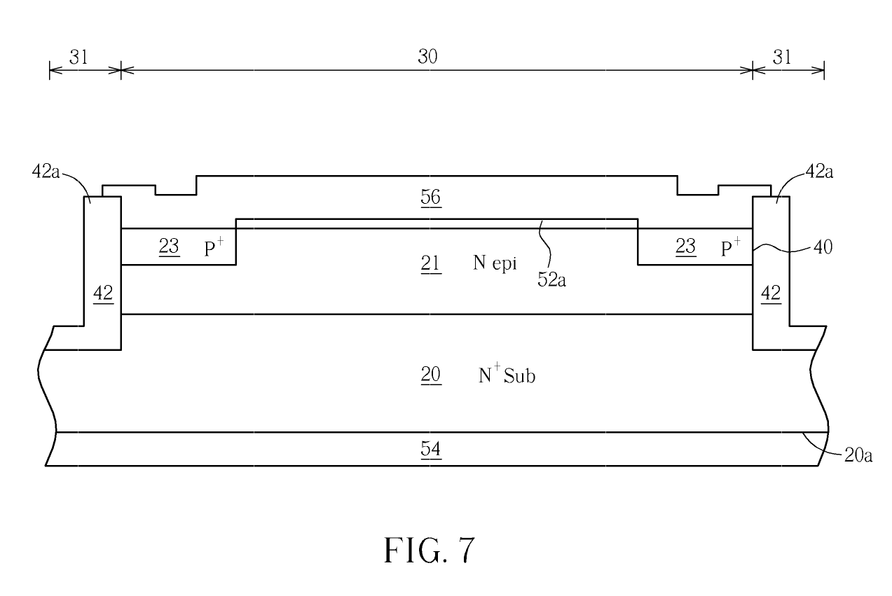

As shown in FIG. 7, after stripping the photoresist pattern 70, a thermal oxidation process is performed to form an insulation layer 42 such as a silicon dioxide on the vertical sidewall and bottom of the annular, recessed trench region 40. The insulation layer 42 has a thickness of about 0.5 micrometers. The insulation layer 42 has an upwardly protruding portion 42a having a height of about 0.5 micrometers above the surface of the N type epitaxial silicon layer 21. The upwardly protruding portion 42a functions as a dam for blocking solder paste overflow during the subsequent soldering process.

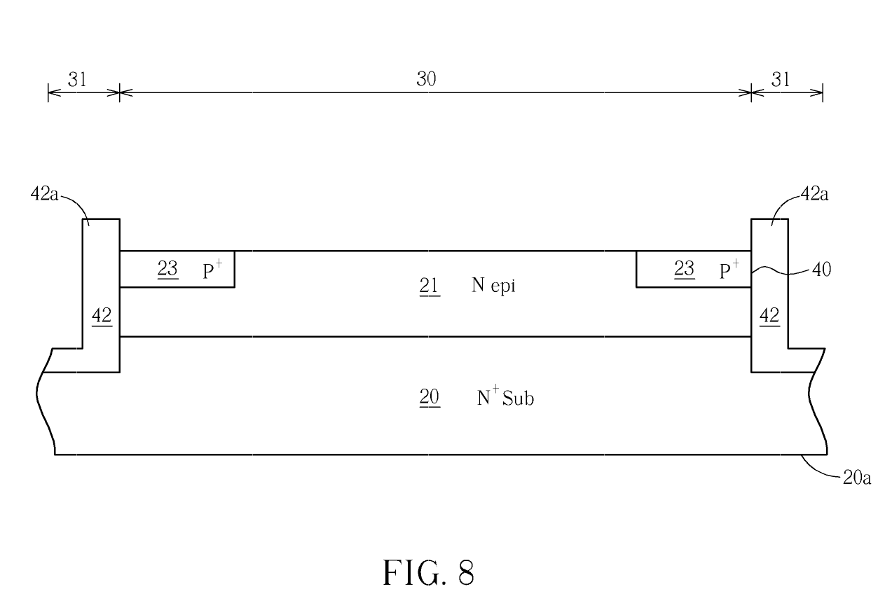

As shown in FIG. 8, an etching process is carried out to selectively remove the remanent silicon nitride layer 56. Thereafter, another etching process is performed to selectively remove the silicon oxide layer 52a, thereby exposing the top surface of the N type epitaxial silicon layer 21. After removing the silicon oxide layer 52a, a polishing process such as chemical mechanical polishing (CMP) is performed to remove the thick silicon oxide layer 54 from the backside 20a of the N type heavily doped silicon substrate 20, thereby exposing the backside 20a of the N type heavily doped silicon substrate 20.

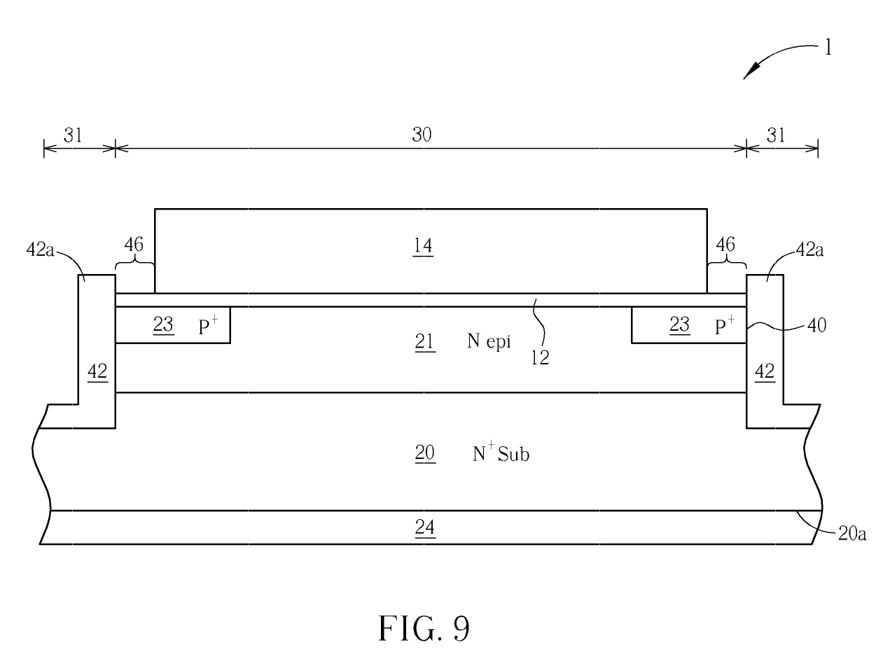

As shown in FIG. 9, a silicide layer 12 such as NiSi is formed on the top surface of the N type epitaxial silicon layer 21 within the active area 30. Subsequently, a conductive layer 14 and a conductive layer 24 are formed on the silicide layer 12 and on the backside 20a of the N type heavily doped silicon substrate 20 respectively. The conductive layers 14 and 24 may be composed of Ti, Ni, Ag or any combination thereof. According to the preferred embodiment of this invention, the silicide layer 12 covers the entire active area 30, while the conductive layer 14 does not covers the entire active area 30, instead, the conductive layer 14 is pull back and maintains an annular space 46, for example, 5-15 micrometers, between the conductive layer 14 and the annular, recessed trench region 40 that surrounds the N type epitaxial silicon layer 21. According to another embodiment of this invention, the silicide layer 12 is TiSi and the conductive layer 14 is Ni, Ag or combination thereof.

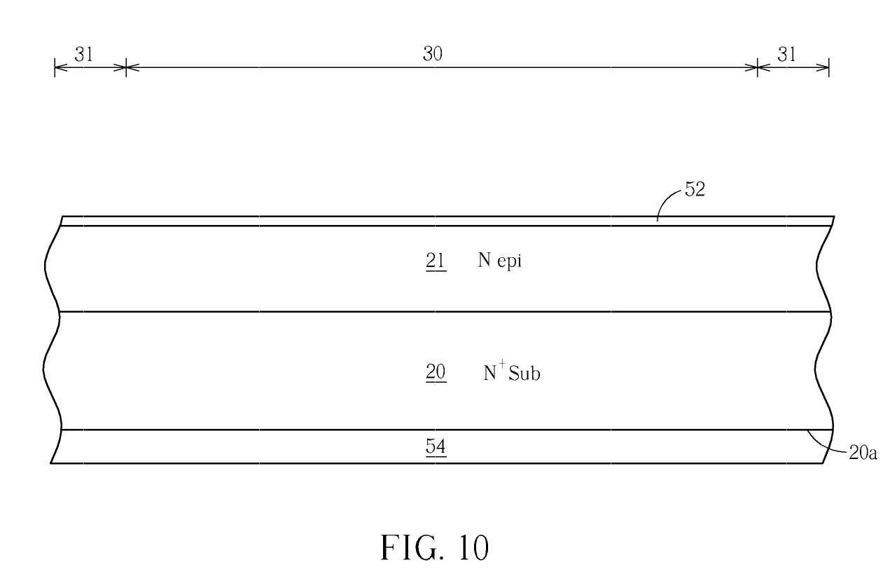

FIG. 10 to FIG. 16 are schematic, cross-sectional diagrams showing the process steps of fabricating a Schottky diode device structure according to another embodiment of this invention, wherein like numeral numbers designate like elements, layers or regions. As shown in FIG. 10, likewise, an N type heavily doped silicon substrate 20 is provided. A thick silicon oxide layer 54 is formed on the backside 20a of the N type heavily doped silicon substrate 20. The thick silicon oxide layer 54 has a thickness of about 4000-6000 angstroms. An epitaxial silicon growth process is performed to grow an N type epitaxial silicon layer 21 on the N type heavily doped silicon substrate 20. Thereafter, an oxidation process is carried out to form a thin silicon oxide layer 52 on the N type epitaxial silicon layer 21. The thin silicon oxide layer 52 has a thickness of about 500 angstroms.

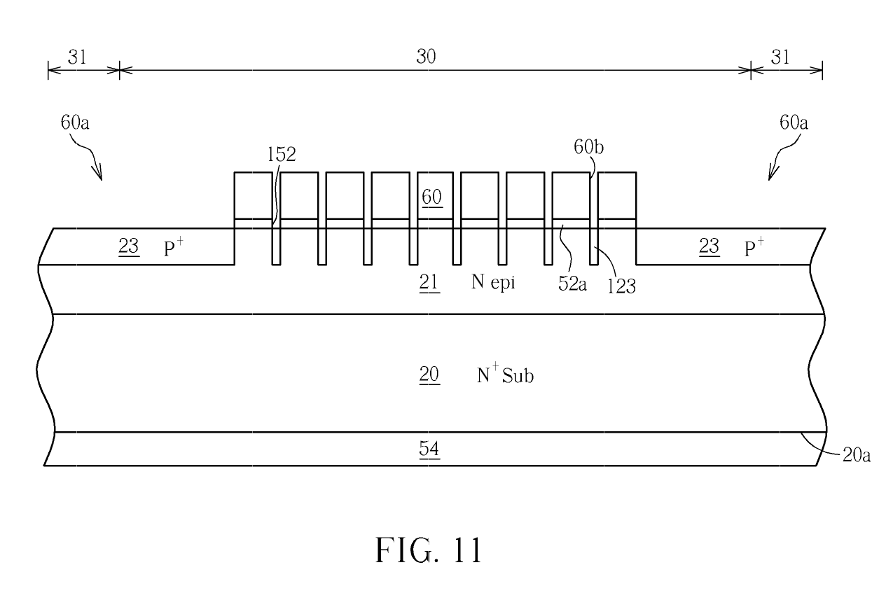

As shown in FIG. 11, a photoresist pattern 60 is formed on the silicon oxide layer 52. The photoresist pattern 60 has an opening 60a that defines the surface area of the N type epitaxial silicon layer 21 to be doped with P type dopants. It is noteworthy that the opening 60a overlaps with a periphery of the active area 30 and the entire scribe line region 31. The photoresist pattern 60 also has a plurality of apertures 60b. Subsequently, an ion implantation process is carried out to implant P type dopants into the N type epitaxial silicon layer 21 through the opening 60a and apertures 60b, thereby forming a P⁺ guard ring 23 and a plurality of P⁺ regions 123. After the ion implantation process, an etching process is performed to remove a portion of the thin silicon oxide layer 52 through the opening 60a, thereby forming silicon oxide layer 52a with a plurality of openings 152. The photoresist pattern 60 is then stripped off. According to another embodiment of this invention, after forming the P⁺ guard ring 23 and the P⁺ regions 123, the photoresist pattern 60 is first stripped, and the thin silicon oxide layer 52 is then completely removed.

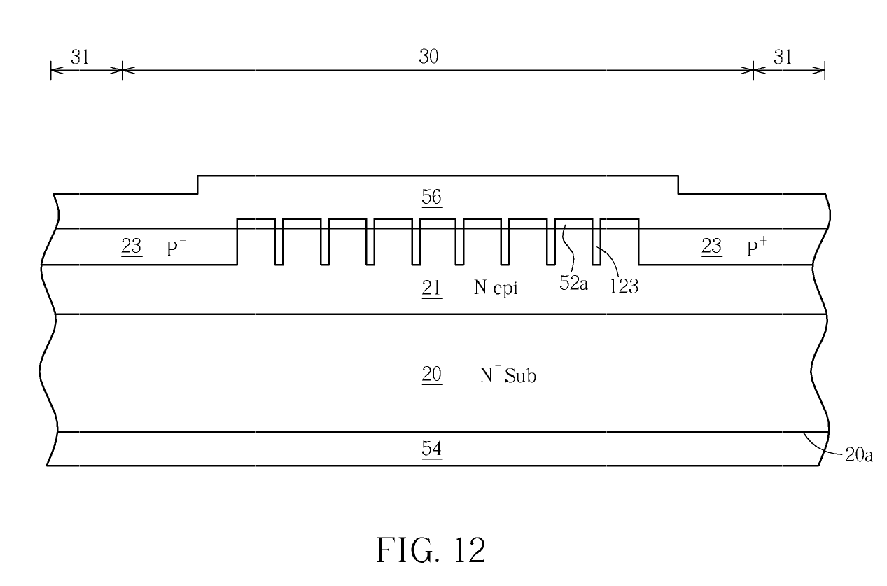

As shown in FIG. 12, after stripping the photoresist pattern 60, a thermal drive-in process is carried out to activate the dopants in the P⁺ guard ring 23 and the P⁺ regions 123. A chemical vapor deposition (CVD) process is performed to deposit a conformal silicon nitride layer 56 on the N type epitaxial silicon layer 21 and on the silicon oxide layer 52a. According to the preferred embodiment of this invention, the silicon nitride layer 56 has a thickness of about 800-1200 angstroms.

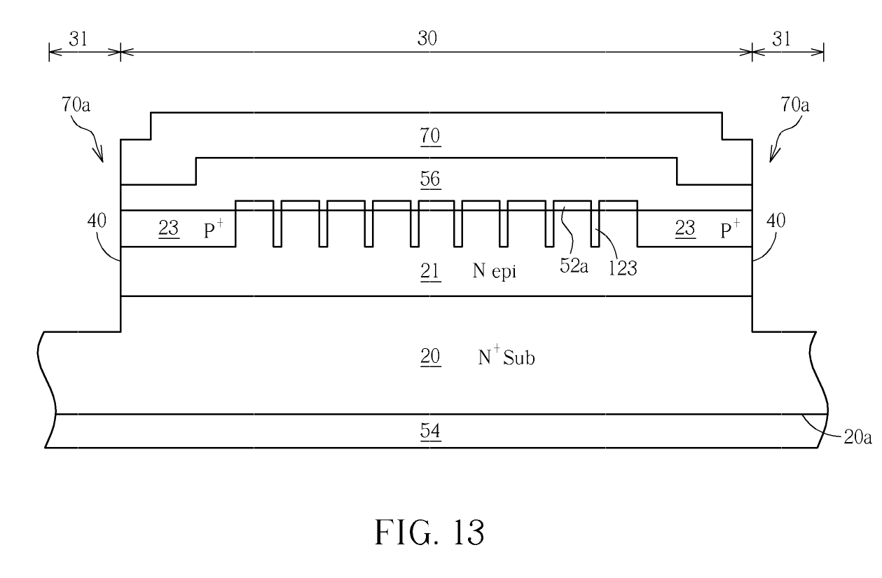

As shown in FIG. 13, a photoresist pattern 70 is formed on the silicon nitride layer 56. The photoresist pattern 70 has an opening 70a that defines and exposes the scribe line region 31. Subsequently, using the photoresist pattern 70 as an etch hard mask, a plasma dry etching process is carried out to anisotropically etch through the silicon nitride layer 56, the P⁺ guard ring 23, the N type epitaxial silicon layer 21, down deep to the N type heavily doped silicon substrate 20. At this point, an island like active area 30 and an annular, recessed trench region 40 are formed concurrently. The annular, recessed trench region 40 has a width of about 30 micrometers and a depth that is greater than the thickness of the N type epitaxial silicon layer 21. According to the preferred embodiment of this invention, the annular, recessed trench region 40 has a depth of about 10 micrometers. The photoresist pattern 70 is then removed.

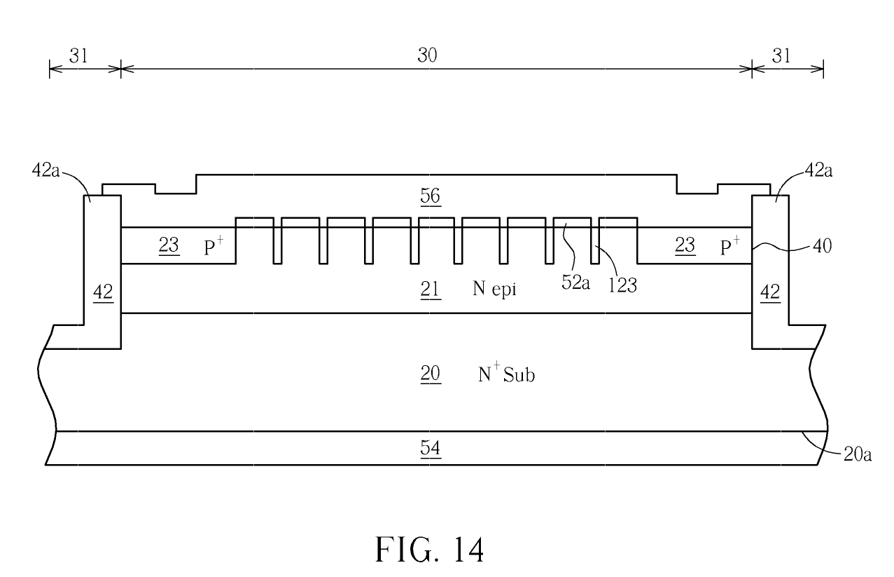

As shown in FIG. 14, after stripping the photoresist pattern 70, a thermal oxidation process is performed to form an insulation layer 42 such as a silicon dioxide on the vertical sidewall and bottom of the annular, recessed trench region 40. The insulation layer 42 has a thickness of about 0.5 micrometers. The insulation layer 42 has an upwardly protruding portion 42a having a height of about 0.5 micrometers above the surface of the N type epitaxial silicon layer 21. The upwardly protruding portion 42a functions as a dam for blocking solder paste overflow during the subsequent soldering process.

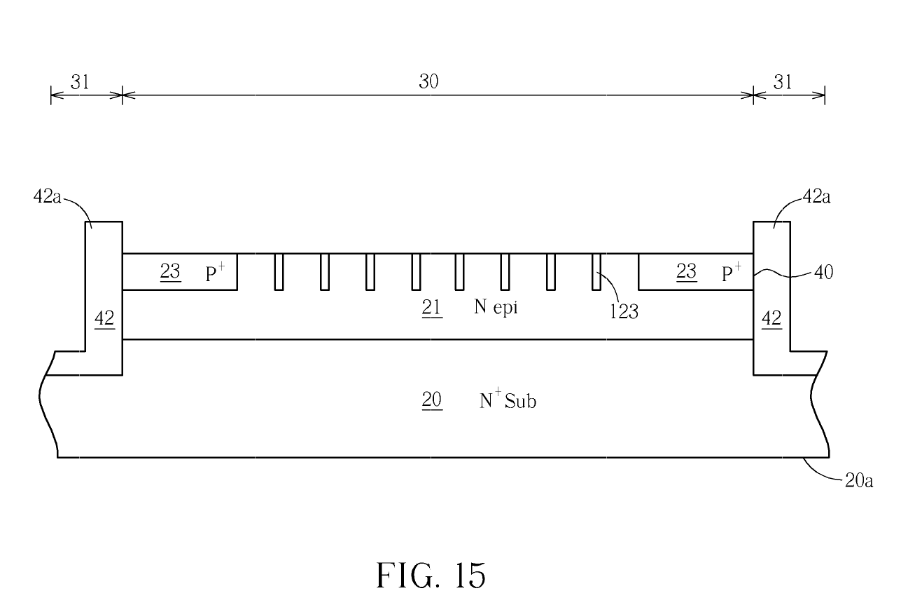

As shown in FIG. 15, an etching process is carried out to selectively remove the remanent silicon nitride layer 56. Thereafter, another etching process is performed to selectively remove the silicon oxide layer 52a, thereby exposing the top surface of the N type epitaxial silicon layer 21. After removing the silicon oxide layer 52a, a polishing process such as chemical mechanical polishing (CMP) is performed to remove the thick silicon oxide layer 54 from the backside 20a of the N type heavily doped silicon substrate 20, thereby exposing the backside 20a of the N type heavily doped silicon substrate 20.

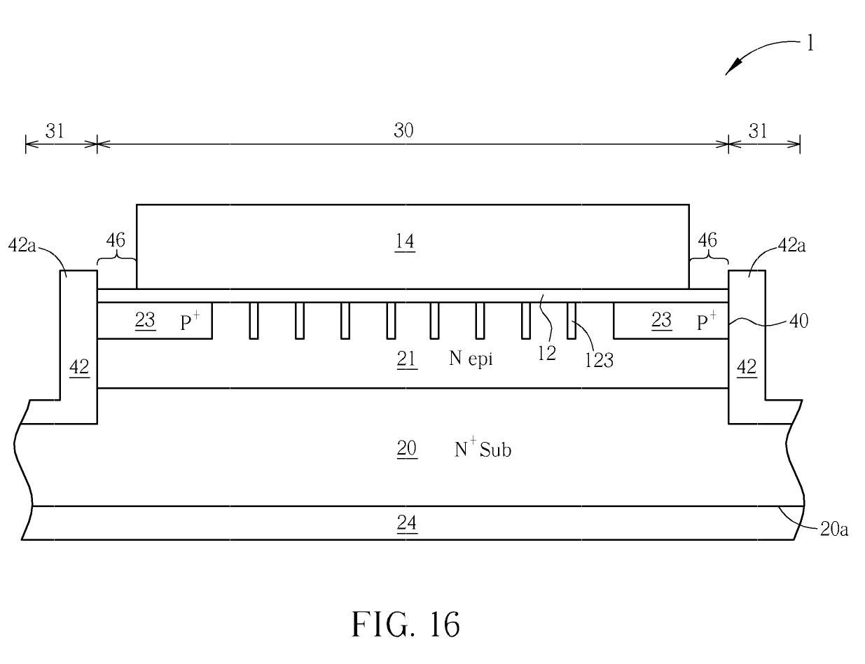

As shown in FIG. 16, a silicide layer 12 such as NiSi is formed on the top surface of the N type epitaxial silicon layer 21 within the active area 30. Subsequently, a conductive layer 14 and a conductive layer 24 are formed on the silicide layer 12 and on the backside 20a of the N type heavily doped silicon substrate 20 respectively. The conductive layers 14 and 24 may be composed of Ti, Ni, Ag or any combination thereof. According to the preferred embodiment of this invention, the silicide layer 12 covers the entire active area 30, while the conductive layer 14 does not covers the entire active area 30, instead, the conductive layer 14 is pull back and maintains an annular space 46, for example, 5-15 micrometers, between the conductive layer 14 and the annular, recessed trench region 40 that surrounds the N type epitaxial silicon layer 21. According to another embodiment of this invention, the silicide layer 12 is TiSi and the conductive layer 14 is Ni, Ag or combination thereof.

Those skilled in the art will readily observe that numerous modifications and alterations of the device and method may be made while retaining the teachings of the invention.

What is claimed is:

1. A Schottky diode device structure with an extended guard ring, comprising:
a silicon substrate;
an epitaxial silicon layer on the silicon substrate;
an annular trench in a scribe line region encompassing the epitaxial silicon layer;
an insulation layer at least on a sidewall of the annular trench;
a silicide layer on the epitaxial silicon layer;
a conductive layer on the silicide layer, the conductive layer being spaced apart from the insulation layer; and
a guard ring in the epitaxial silicon layer and the guard ring butting the insulation layer.

2. The Schottky diode device structure according to claim 1 wherein the annular trench defines an active area.

3. The Schottky diode device structure according to claim 2 wherein the silicide layer covers entire said active area.

4. The Schottky diode device structure according to claim 1 wherein the annular trench has a depth that is deeper then a thickness of the epitaxial silicon layer.

5. The Schottky diode device structure according to claim 1 wherein the annular trench has a depth of about 10 micrometers.

6. The Schottky diode device structure according to claim 1 wherein the insulation layer includes an upwardly protruding portion that is higher than a top surface of the silicide layer.

7. The Schottky diode device structure according to claim 6 wherein the upwardly protruding portion has a height that is 0.5 micrometers above the top surface of the silicide layer.

8. The Schottky diode device structure according to claim 1 wherein the silicon substrate is an N type heavily doped silicon substrate.

9. The Schottky diode device structure according to claim 1 wherein the epitaxial silicon layer is an N type epitaxial silicon layer.

10. The Schottky diode device structure according to claim 1 wherein the insulation layer comprises silicon oxide.

11. The Schottky diode device structure according to claim 1 wherein the silicide layer comprises NiSi, PtSi or TiSi.

12. The Schottky diode device structure according to claim 1 wherein the conductive layer comprises Ti, Ni, Ag or combinations thereof.

13. The Schottky diode device structure according to claim 1 wherein the guard ring is a P⁺ guard ring.

14. A method for fabricating a Schottky diode device, comprising:
providing a silicon substrate;
growing an epitaxial silicon layer on the silicon substrate;
forming a first dielectric layer on the epitaxial silicon layer;
performing an ion implantation process to form a guard ring in the epitaxial silicon layer;
removing the first dielectric layer;
forming a second dielectric layer on the epitaxial silicon layer;
etching the second dielectric layer, the guard ring, the epitaxial silicon layer and the silicon substrate to form an annular trench;
forming an insulation layer on a sidewall of the annular trench;
removing the second dielectric layer thereby exposing the epitaxial silicon layer;
forming a silicide layer on the epitaxial silicon layer; and
forming a conductive layer on the silicide layer.

15. The method of claim 14 wherein the annular trench has a depth that is greater than a thickness of the epitaxial silicon layer.

16. The method of claim 14 wherein before removing the second dielectric layer, a thermal drive-in process is carried out to activate dopants in the guard ring.

17. The method of claim 14 wherein the first dielectric layer is a silicon oxide layer.

18. The method of claim 14 wherein the second dielectric layer is a silicon nitride layer.

19. The method of claim 14 wherein the insulation layer includes an upwardly protruding portion that is higher than a top surface of the silicide layer.
